(19) United States
(12) Patent Application Publication
(10) Pub. No.: US 2026/0082996 A1
(43) Pub. Date: Mar. 19, 2026

(54) WAFER BONDING PROCESS

(71) Applicant: Applied Materials, Inc., Santa Clara, CA (US)

(72) Inventors: ELLIE YIEH, San Jose, CA (US); NIKOLAOS BEKIARIS, Campbell, CA (US); LEI XUE, Santa Clara, CA (US); KAI MA, Palo Alto, CA (US)

(21) Appl. No.: 18/888,042

(22) Filed: Sep. 17, 2024

(51) Int. Cl. H01L 25/16; H01L 23/00; H10B 80/00

(52) U.S. Cl. CPC H10W 90/00; H10B 80/00; H10W 90/732

(57) ABSTRACT

Embodiments described herein relate to an apparatus, that includes a substrate, where the substrate includes a semiconductor material. In an embodiment, a first layer is on the substrate, and the first layer includes a first dielectric material. In an embodiment, a device is embedded within the first layer. In an embodiment, the apparatus further includes a second layer that is embedded within the first layer. In an embodiment, the second layer includes a second dielectric material, and a sidewall of the second layer is exposed.

### BACKGROUND

### 1) Field

Embodiments relate to the field of semiconductor manufacturing and, in particular, a substrate-to-substrate bonding process.

### 2) Description of Related Art

Wafer-to-wafer bonding has become more prevalent in advanced semiconductor manufacturing processes. Wafer-to-wafer bonding enables the formation of improved three dimensional architectures. For example, a first wafer may comprise memory devices, and a second wafer may comprise logic devices. The wafer-to-wafer bonding allows for both the logic devices and the memory devices to be vertically stacked within a die. Other three dimensional architectures may include 3D DRAM or the like.

While wafer-to-wafer bonding has many potential application spaces, the assembly process for the wafer-to-wafer bonding is not without issue. Particularly, the bonding interface (which may be a dielectric material, such as an oxide)may have a relatively low bond strength. Materials with higher bond strengths are not able to be used since the different materials interfere with the processing used to form vias to the devices on the bottom wafer. Further, the edge region of the wafers may include stepped surfaces and/or other recesses or depressions due to the manufacturing process used to form the bonding interface. As such, the outer edges of the opposing wafers may not contact each other. This can lead to edge defects or the like.

### SUMMARY

Embodiments described herein relate to an apparatus, that includes a substrate, where the substrate includes a semiconductor material. In an embodiment, a first layer is on the substrate, and the first layer includes a first dielectric material. In an embodiment, a device is embedded within the first layer. In an embodiment, the apparatus further includes a second layer that is embedded within the first layer. In an embodiment, the second layer includes a second dielectric material, and a sidewall of the second layer is exposed.

Embodiments described herein relate to an apparatus that includes a substrate, and a first layer over the substrate. In an embodiment, the first layer includes a recess into a sidewall of the first layer. In an embodiment, a second layer at least partially fills the recess, and the second layer is a different material than the first layer. In an embodiment, the second layer forms a ring around at least a portion of the first layer.

Embodiments described herein relate to a method that includes applying a first film along a first edge profile of a first substrate, and applying a second film along a second edge profile of a second substrate. In an embodiment, the method may further include bonding the first substrate to the second substrate, so that a first bond interface is formed between the first film and the second film, and a second bond interface is formed between the first substrate and the second substrate.

### DESCRIPTION OF THE DRAWINGS

FIG. 1A is a cross-sectional illustration of a first substrate and a second substrate that both comprise devices embedded in dielectric layers, in accordance with an embodiment.

FIG. 1B is a cross-sectional illustration of the first substrate bonded to the second substrate with a cavity along edges of the combined substrate, in accordance with an embodiment.

FIG. 2A is a cross-sectional illustration of a first substrate with a bonding layer and a second substrate with a bonding layer, in accordance with an embodiment.

FIG. 2B is a cross-sectional illustration of the first substrate bonded to the second substrate with a cavity along edges of the combined substrate, in accordance with an embodiment.

FIG. 2C is a cross-sectional illustration of the combined substrate with holes formed through the dielectric layers and the bonding layers, in accordance with an embodiment.

FIG. 2D is a zoomed in cross-sectional illustration of a hole in the combined substrate that illustrates offset sidewalls through the bonding layers, in accordance with an embodiment.

FIG. 3A is a cross-sectional illustration of a first substrate and a second substrate with a bonding layer on edge recesses of the first substrate and the second substrate, in accordance with an embodiment.

FIG. 3B is a cross-sectional illustration of the first substrate and the second substrate with the bonding layers planarized with the top surfaces of the first substrate and the second substrate, in accordance with an embodiment.

FIG. 3C is a plan view illustration of the first substrate that illustrates the bonding layer forming a ring around a perimeter of a portion of the first substrate, in accordance with an embodiment.

FIG. 3D is a cross-sectional illustration of the first substrate bonded to the second substrate to form a combined substrate, in accordance with an embodiment.

FIG. 3E is a cross-sectional illustration of the combined substrate after holes are formed through dielectric layers to expose devices embedded in the first substrate, in accordance with an embodiment.

FIG. 3F is a zoomed in cross-sectional illustration of a hole in the combined substrate that illustrates a planar sidewall, in accordance with an embodiment.

FIG. 4A is a cross-sectional illustration of a combined substrate that illustrates bonding layers that comprise different materials, in accordance with an embodiment.

FIG. 4B is a cross-sectional illustration of a combined substrate that includes a cavity into sidewalls that have stepped surfaces, in accordance with an embodiment.

FIG. 5 is a flow diagram depicting a process for substrate-to-substrate bonding that includes a bonding layer around a perimeter of the substrate, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include substrate-to-substrate bonding processes that use a multi-film interface in order to improve bond strength across an entire width of the substrates. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, interest in substrate-to-substrate bonding is increasing due to the advanced three dimensional structures that can be fabricated using such processes. For example, substrate-to-substrate bonding may allow for a first substrate that comprises memory devices to be bonded over a second substrate that comprises logic devices. As such, the substrate-to-substrate bonding allows for both logic devices and the memory devices to be vertically stacked within a die. Other three dimensional architectures may include 3D DRAM or the like. In other embodiments, substrate-to-substrate bonding may be used in order to attach a device wafer to a carrier wafer. That is, in some instances active devices may be provided on a single one of the substrates.

However, existing substrate-to-substrate bonding processes are limited by a poor bond strength between the first substrate and the second substrate. Typically, a dielectric material is provided at the bonding surfaces of both substrates. However, the dielectric material is tuned for devices fabrication processes and may have suboptimal bond strengths. Switching to high bonding strength dielectrics is not a simple substitution since new etching processes would also need to be developed.

Further, the way devices are fabricated within the dielectric layers results in the formation of recessed surfaces towards the edge of the substrates. When the two substrates are bonded together, the recessed surfaces on each substrate are spaced apart from each other. This prevents the formation of a continuous bonding interface that extends across the entire width of the combined substrate. As such, edge defects are common due to the further diminished bond strength.

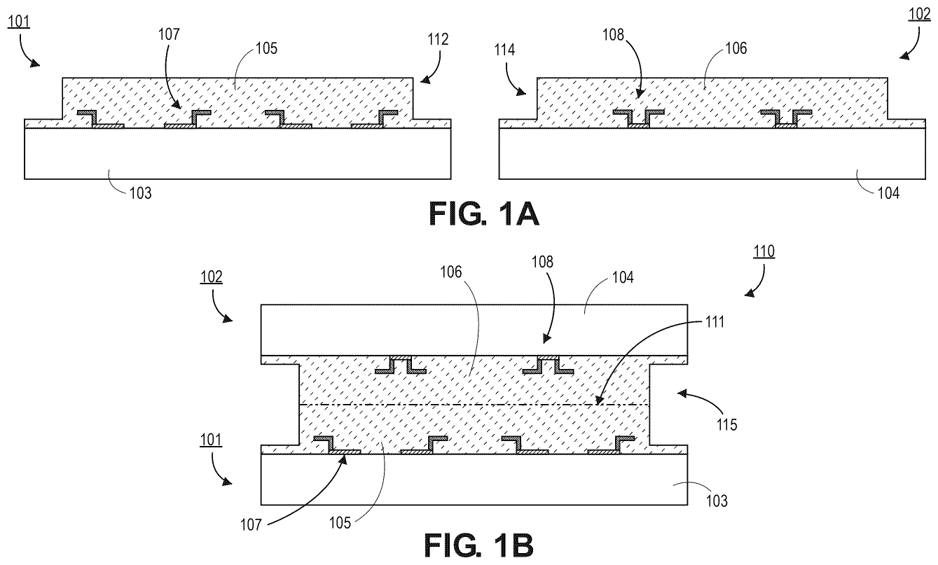

An example of such an issue is shown in FIGS. 1A and 1B. Referring now to FIG. 1A, cross-sectional illustrations of a first substrate 101 and a second substrate 102 are shown. The first substrate 101 and the second substrate 102 may have similar form factors. For example, the first substrate 101 and the second substrate 102 may comprise standard wafer form factors (e.g., 300 mm or the like).

The first substrate 101 may comprise a first layer 103 and an overlying second layer 105. The first layer 103 may be a semiconductor material, such as silicon or the like. The second layer 105 may comprise a dielectric material, such as silicon dioxide (e.g., SiO₂). The second layer 105 may comprise a plurality of sub-layers such as one or more of SiO, SiN, SiON, SiCN, or the like. The plurality of sub-layers may be built up during the fabrication of devices 107 (e.g., transistor devices, electrical routing, and/or the like). The multiple sub-layer formation of the second layer 105 may result in a recess 112 being formed along edges of the first substrate 101.

Similarly, the second substrate 102 may comprise a first layer 104 and an overlying second layer 106. The first layer 104 may be a semiconductor material, such as silicon or the like. The second layer 106 may comprise a dielectric material, such as silicon dioxide. The second layer 106 may comprise a plurality of sub-layers of silicon dioxide that are built up during the fabrication of devices 108 (e.g., transistor devices, electrical routing, and/or the like). The multiple sub-layer formation of the second layer 106 may result in a recess 114 being formed along edges of the second substrate 102.

Referring now to FIG. 1B, a cross-sectional illustration of a combined substrate 110 is shown. The combined substrate 110 may be the result of bonding the second layer 105 of the first substrate 101 to the second layer 106 of the second substrate 102. That is, the bonding may include a dielectric-to-dielectric bonding process. The bonding may include an annealing process. As such, an interface 111 may be provided between the second layer 105 of the first substrate 101 and the second layer 106 of the second substrate 102. While a seam for the interface 111 is shown in FIG. 1B, the fusion bonding process may result in a combined substrate 110 that appears to be seamless depending on the imaging or metrology used to inspect the combined substrate 110.

As noted above, the dielectric-to-dielectric bond of opposing silicon dioxide surfaces may not be particularly strong. Additionally, the recesses 112 and 114 of the first substrate 101 and the second substrate 102, respectively, result in the formation of a cavity 115 at the edge of the combined substrate 110. As such, the edges of the combined substrate 110 are particularly prone to damage and/or defects.

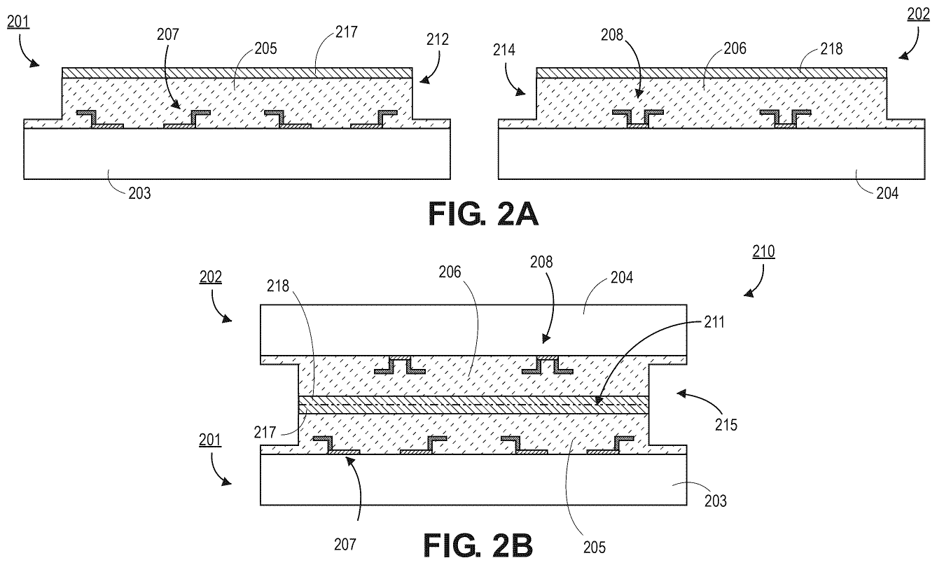

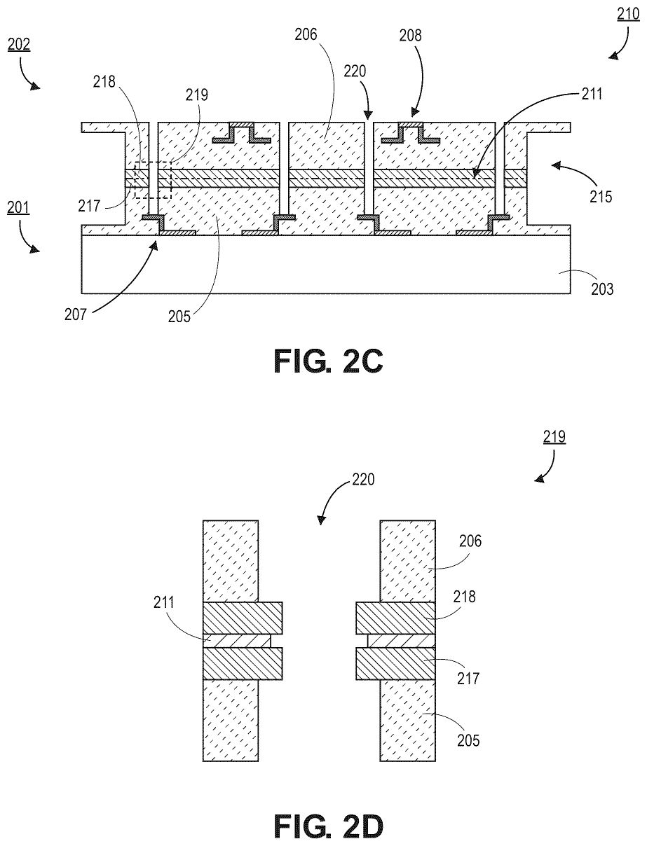

One approach has been to apply a dedicated bonding layer over the dielectric second layers of each substrate. For example, a silicon carbon nitride (e.g., SiCN) layer may be provided over the silicon dioxide layers. An example of such a solution is shown in FIG. 2A-2D.

Referring now to FIG. 2A, cross-sectional illustrations of a first substrate 201 and a second substrate 202 are shown. The first substrate 201 and the second substrate 202 may be similar to the first substrate 101 and the second substrate 102 described above. For example, the first substrate 201 and the second substrate 202 may comprise standard wafer form factors (e.g., 300 mm or the like).

The first substrate 201 may also comprise a first layer 203 and an overlying second layer 205. The first layer 203 may be a semiconductor material, such as silicon or the like. The second layer 205 may comprise a dielectric material, such as silicon dioxide. The second layer 205 may comprise a plurality of sub-layers of silicon dioxide that are built up during the fabrication of devices 207 (e.g., transistor devices, electrical routing, and/or the like). The multiple sub-layer formation of the second layer 205 may result in a recess 212 being formed along edges of the first substrate 201.

Similarly, the second substrate 202 may comprise a first layer 204 and an overlying second layer 206. The first layer 204 may be a semiconductor material, such as silicon or the like. The second layer 206 may comprise a dielectric material, such as silicon dioxide. The second layer 206 may comprise a plurality of sub-layers of silicon dioxide that are built up during the fabrication of devices 208 (e.g., transistor devices, electrical routing, and/or the like). The multiple sub-layer formation of the second layer 206 may result in a recess 214 being formed along edges of the second substrate 202.

In an embodiment, a bonding layer 217 may be provided over the second layer 205 of the first substrate 201, and a bonding layer 218 may be provided over the second layer 206 of the second substrate 202. The bonding layers 217 and 218 may comprise a dielectric material that is selected to provide improved bonding strength between the first substrate 201 and the second substrate 202. For example, the bonding layers 217 and 218 may comprise SiCN.

Referring now to FIG. 2B, a cross-sectional illustration of a combined substrate 210 is shown. The combined substrate 210 may be the result of bonding the bonding layer 217 of the first substrate 201 to the bonding layer 218 of the second substrate 202. That is, the bonding may include a dielectric-to-dielectric bonding process. The bonding may include the application of pressure with an annealing process. As such, an interface 211 may be provided between the bonding layer 217 of the first substrate 201 and the bonding layer 218 of the second substrate 202. While a seam for the interface 211 is shown in FIG. 2B, the fusion bonding process may result in a combined substrate 210 that appears to be seamless depending on the imaging or metrology used to inspect the combined substrate 210.

While the bond strength is improved along the surfaces that are in contact with each other, the combined substrate 210 still suffers from weakness at the edge of the combined substrate 210 due to the presence of the cavity 215. Additionally, the introduction of the bonding layers 217 and 218 between the second layers 205 and 206 makes subsequent processing more complicated.

Referring now to FIG. 2C, a cross-sectional illustration of the combined substrate 210 after the first layer 204 of the second substrate 202 is removed and holes 220 (e.g., via openings) are formed through the dielectric layers is shown. The holes 220 may be used to expose portions (e.g., pads, traces, etc.) of the underlying devices 207 in order to make electrical contact to the devices 207 (e.g., by forming electrically conductive vias in the holes 220). Typically, an etching process is used to form the holes 220 through the dielectric layers in the combined substrate 210. However, with different dielectric materials along the path of the holes 220 (e.g., SiO₂ and SiCN), a single etching chemistry may not provide the desired sidewall profile for the holes 220. As such, it may be more difficult to plate the vias.

Referring now to FIG. 2D, a zoomed in cross-sectional illustration of a region 219 of one of the holes 220 in FIG. 2C is shown, in accordance with an embodiment. As shown, the hole 220 has a non-uniform sidewall profile across the bonding layers 217 and 218. For example, sidewall surfaces of the bonding layers 217 and 218 may extend into the hole 220 past the sidewalls of the second layers 205 and 206. Interface layer 211 is also shown in FIG. 2D. Interface layer 211 may have a different chemical formula than the bonding layers 217 and 218 due to the bonding process used to form the combined substrate 210. The interface layer 211 may also etch at a different rate than the bonding layers 217 and 218. As such, a stepped profile along the hole 220 may be provided in some embodiments. The extensions of the bonding layers 217 and 218 may result in a constriction point (i.e., a localized reduction in a diameter of the hole). This can lead to the formation of voids within the via that is to be plated in the hole 220. Voids negatively impact the flow of current and can lead to device defects and/or failures within the device.

Accordingly, embodiments disclosed herein may include a substrate-to-substrate bonding process that leverages the high bonding strength of a second dielectric material while also allowing for the use of existing etching processes in order to form high quality electrically conductive vias within the combined substrate. Particularly, embodiments disclosed herein may include filling the edge recesses of the individual substrates with a fill layer that has a high bond strength. During the bonding process, the second layers are bonded directly together at a center of the combined substrate, and the fill layers are bonded directly together at an edge of the combined substrate.

As such, the edge regions of the combined substrate have an improved bond strength and are less prone to damage. Since the center of the combined substrate does not have an intervening dielectric layer for bonding, the existing etching processes may be used to form the holes used to form vias. Accordingly, the combined substrate includes improved mechanical durability while also maintaining a desired electrical performance.

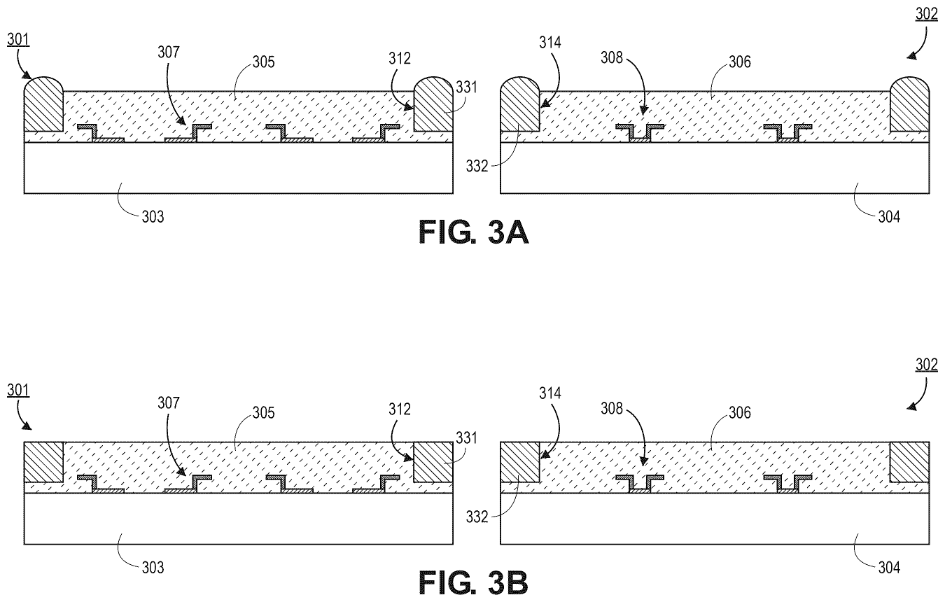

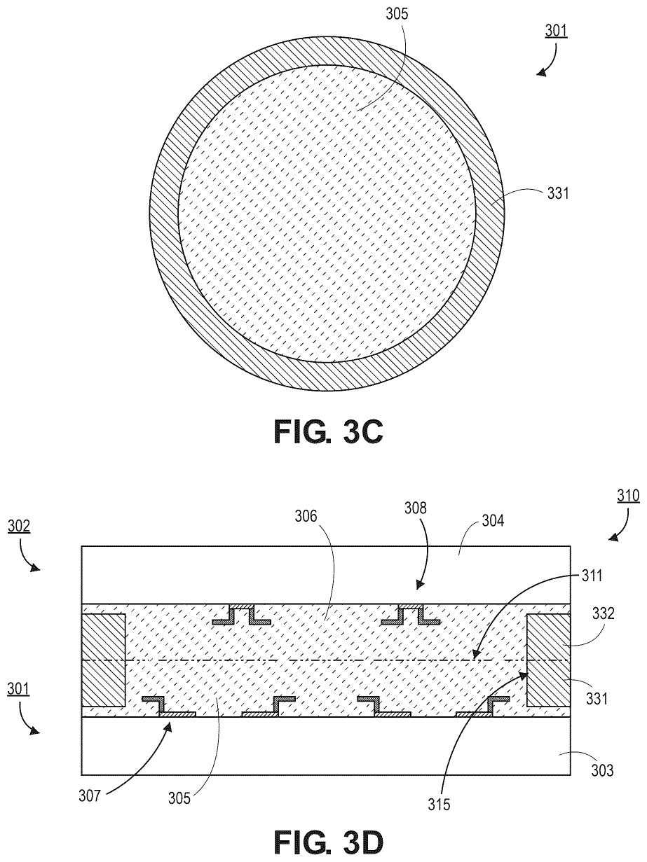

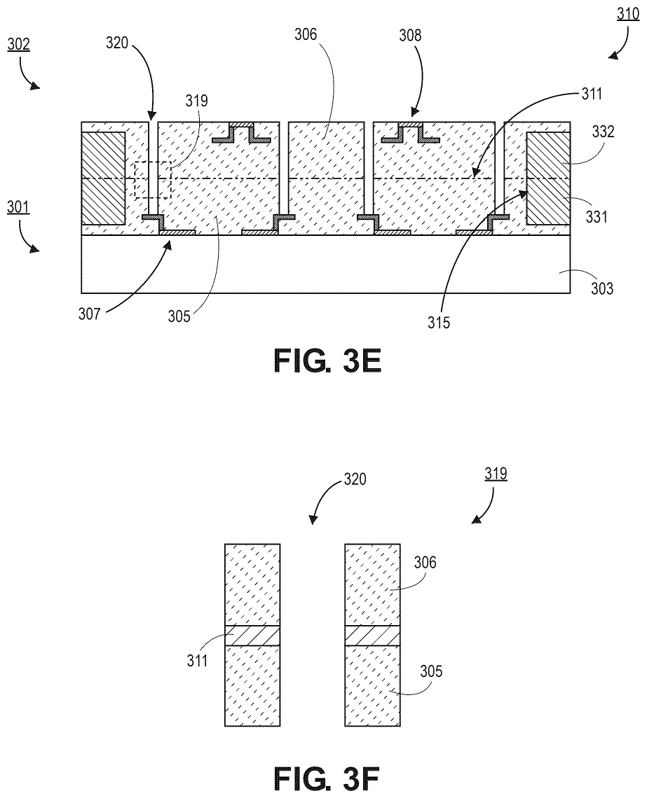

Referring now to FIG. 3A-3F, a series of cross-sectional illustrations depicting a process for forming a combined substrate 310 using a substrate-to-substrate bonding process that includes fill layers 331 and 332 around perimeters of the first substrate 301 and the second substrate 302, respectively is shown, in accordance with an embodiment.

Referring now to FIG. 3A, a cross-sectional illustration that depicts a first substrate 301 and a second substrate 302 is shown, in accordance with an embodiment. The first substrate 301 and the second substrate 302 may be similar to the first substrate 101 and the second substrate 102 described above. For example, the first substrate 301 and the second substrate 302 may comprise standard wafer form factors (e.g., 300 mm or the like).

The first substrate 301 may comprise a first layer 303 and an overlying second layer 305. The first layer 303 may be a semiconductor material, such as silicon or the like. In an embodiment, the second layer 305 may comprise a dielectric material, such as silicon dioxide. The second layer 305 may comprise a plurality of sub-layers of silicon dioxide that are built up during the fabrication of devices 307 (e.g., transistor devices, electrical routing, and/or the like). In some embodiments, the devices 307 may comprise memory devices, logic devices, power delivery devices, power management devices, or the like. The multiple sub-layer formation of the second layer 305 may result in a recess 312 being formed along edges of the first substrate 301.

Similarly, the second substrate 302 may comprise a first layer 304 and an overlying second layer 306. The first layer 304 may be a semiconductor material, such as silicon or the like. In some embodiments, the first layer 304 of the second substrate 302 is the same material as the material for the first layer 303 of the first substrate 301. Though, in other embodiments, the first layer 304 may be a different semiconductor material than the first layer 303. For example, the first layer 303 may comprise silicon and the first layer 304 may comprise a III-V semiconductor material.

The second layer 306 of the second substrate 302 may comprise a dielectric material, such as silicon dioxide. The second layer 306 of the second substrate 302 may be the same material as the second layer 305 of the first substrate 301. The second layer 306 may comprise a plurality of sub-layers of silicon dioxide that are built up during the fabrication of devices 308 (e.g., transistor devices, electrical routing, and/or the like). In an embodiment, the devices 308 may be similar to the devices 307. In other embodiments, the devices 308 may be different than the devices 307. For example, the devices 307 may include logic devices, and the devices 308 may comprise memory devices. The multiple sub-layer formation of the second layer 306 may result in a recess 314 being formed along edges of the second substrate 302.

In an embodiment, the recesses 312 and 314 may be filled with fill layers 331 and 332, respectively. The fill layers 331 and 332 may be a dielectric material that is different than the dielectric material of the second layers 305 and 306. For example, the fill layers 331 and 332 may comprise a dielectric material that is tuned to provide a high bond strength during the substrate-to-substrate bonding process. The fill layers 331 and 332 may comprise silicon, carbon, and nitrogen (e.g., SiCN), or the fill layers 331 and 332 may comprise aluminum and oxygen (e.g., AlO). Though other, dielectric materials with good bond strengths can be used as well.

In an embodiment, the fill layers 331 and 332 may be selectively deposited into the recesses 312 or 314. In one embodiment, a mask is provided over the top surface of the second layers 305 and 306 and a dry deposition process is used to deposit the fill layers 331 and 332 into the recesses 312 and 314. For example, chemical vapor deposition (CVD), plasma enhanced CVD (PECVD), physical vapor deposition (PVD), atomic layer deposition (ALD), plasma enhanced ALD (PEALD), or the like may be used to deposit the fill layers 331 and 332.

In other embodiments, a selectively formed plasma may be used to deposit the fill layers 331 and 332 into the recesses 312 and 314. For example, a ring plasma may be formed within a chamber where the ring plasma is positioned over an outer edge of the first substrate 301 and the second substrate 302. As such, the deposition will selectively occur over the recesses 312 and 314. In the illustrated embodiment, the fill layers 331 and 332 may have domed and/or rounded top surfaces that extend above the top surfaces of the second layers 305 and 306.

As can be appreciated, perfect selective deposition may not be possible with some deposition processes. However, a subsequent planarizing process may be used to remove the domed surfaces and any undesired overburden on the second layers 305 and 306. For example, FIG. 3B shows the first substrate 301 and the second substrate 302 after a planarizing process, such as a chemical mechanical planarizing (CMP) process. As shown, the top surfaces of the fill layers 331 and 332 are planarized so that they are substantially coplanar with top surfaces of the second layers 305 and 306. Additionally, the planarizing process exposes the top surface of the second layers 305 and 306 to provide improved bonding.

While substantially coplanar surfaces are shown along the top surfaces of the first substrate 301 and the second substrate 302, other embodiments may include a process that results in surfaces of the fill layers 331 and/or 332 that are non-planar with the top surfaces of the second layers 305 and/or 306, respectively. For example, providing a slight recess, a slight protrusion, a curved surface, or the like may be beneficial for the bonding process in some embodiments. In some instances, an offset between the position of the top surfaces of the fill layers 331 and/or 332 relative to the top surfaces of the second layers 305 and/or 306 may result in improved position registration between the first substrate 301 and the second substrate 302 during bonding.

While selective deposition processes are described as one embodiment, a blanket deposition process may also be used in other embodiments. For example, the fill layers 331 and 332 may be blanket deposited over the second layers 305 and 306. The overburden of the fill layers 331 and 332 may then be polished back with a CMP process or the like in order to expose the second layers 305 and 306 while leaving the fill layers 331 and 332 within the recesses 312 and 314.

In the embodiment shown in FIGS. 3A and 3B, the fill layers 331 and 332 are separated from the first layers 303 and 304 by a portion of the second layers 305 and 306. However, in some embodiments, at least a portion of one or both of the fill layers 331 and 332 may contact the first layers 303 and 304.

Additionally, while the recesses 312 and 314 are shown as being a single recessed surface into the second layers 305 and 306, other embodiments may comprise recesses 312 and 314 with more complex profiles. For example, the recesses 312 and 314 may also have stepped profiles, curved profiles, and/or the like (as will be described in greater detail herein).

Referring now to FIG. 3C, a plan view illustration of the first substrate 301 is shown, in accordance with an embodiment. As shown, the plan view of the first substrate 301 depicts the fill layer 331 as being a ring around a perimeter of a portion of the first substrate 301. For example, the fill layer 331 surrounds a perimeter of a portion of the second layer 305 that is exposed at a top surface of the first substrate 301.

Referring now to FIG. 3D, a cross-sectional illustration of a combined substrate 310 after a substrate-to-substrate bonding process is used to bond the first substrate 301 to the second substrate 302 is shown, in accordance with an embodiment. In some embodiments, the substrate-to-substrate bonding may include a first dielectric-to-dielectric bonding process and a second dielectric-to-dielectric bonding process. For example, the first dielectric-to-dielectric bonding process may refer to the bonding of the second layers 305 and 306 together, and the second dielectric-to-dielectric bonding process may refer to bonding the fill layers 331 and 332 together. While referred to as different processes, it is to be appreciated that the first dielectric-to-dielectric bonding process and the second dielectric-to-dielectric bonding process may be implemented at the same time in some embodiments.

In an embodiment, the bonding may include the application of pressure and/or the application of heat to perform an annealing process. In an embodiment, the annealing temperature may be up to approximately 200° C. or up to approximately 800° C. Though, lower or higher annealing temperatures may also be used in some embodiments. In some embodiments, the first substrate 301 and/or the second substrate 302 may be treated (e.g., with a plasma treatment process) before the bonding operation. For example, plasma exposure may strip carbon and nitrogen from SiCN at the surface of the fill layers 331 and 332. The silicon at the surface of the fill layers 331 and 332 may then bond with each other and with available oxygen to form Si—O—Si bonds the interface 311 between the fill layers 331 and 332. The interface 311 may have a thickness up to approximately 5 nm or up to approximately 10 nm. Though, in some embodiments, the interface 311 may not be discernable between the fill layers 331 and 332 after bonding. That is, the combined fill layers 331 and 332 may appear as a single monolithic structure in some embodiments. In an embodiment, the interface 311 may also extend between the second layers 305 and 306. Similar to above, the seam for the interface 311 shown in FIG. 3B may not be visible or otherwise discernable in the combined substrate 310 in some embodiments.

As can be appreciated from the structure of the combined substrate 310, the fill layers 331 and 332 reinforce the cavities 315 that are formed at the edges of the combined substrate 310. This provides an edge with good bond strength, while also improving structural robustness. Accordingly, damage and/or defects proximate to the edge of the combined substrate 310 may be reduced or eliminated.

Referring now to FIG. 3E, a cross-sectional illustration of the combined substrate 310 after the first layer 304 of the second substrate 302 is removed and holes 320 (e.g., via openings) are formed through the dielectric layers is shown. The holes 320 may be used to expose portions (e.g., pads, traces, etc.) of the underlying devices 307 in order to make electrical contact to the devices 307 (e.g., by forming electrically conductive vias in the holes 320). In an embodiment, an etching process is used to form the holes 320 through the dielectric second layers 305 and 306 in the combined substrate 310. In contrast to the complex etching scheme described above, a single etching chemistry may be used in order to fabricate holes with linear sidewall profiles. As such, subsequent plating to form the vias is easier to control.

In an embodiment, removal of the first layer 304 of the second substrate 302 may expose portions of the devices 308. For example, the exposed portions of the devices 308 may comprise electrically conductive pads or the like. In some embodiments, the pads of the devices may be suitable for hybrid bonding to other substrates (not show), such as a package substrate, an interposer, another die, or the like. While the entire first layer 304 is removed in FIG. 3E, it is to be appreciated that portions of the first layer 304 may persist in the device. For example, semiconductor portions of the first layer 304 may remain proximate to devices 308 in order to provide semiconductor functionality to one or more of the devices 308.

Since the interface 311 may not clearly discernable between one or both of the second layers 305 and 306 and between the fill layers 331 and 332, the combined substrate 310 may appear as a single monolithic dielectric layer over a semiconductor substrate. In such an embodiment, an indication that a substrate-to-substrate bonding process was used may include the presence of a device 307 embedded within the monolithic dielectric layer along a first surface of monolithic dielectric layer that faces the substrate, and the presence of a device 308 embedded within the monolithic dielectric layer along a second surface of the monolithic dielectric layer that faces away from the substrate. Further, a fill layer may be embedded within the monolithic dielectric layer. For example, the fill layer may comprise a different dielectric material than the monolithic dielectric layer, and a sidewall of the fill layer may be exposed (e.g., at the edge of the device). In some instances, the fill layer may be a ring with a height that is smaller than the height of the monolithic dielectric layer, and the fill layer may surrounds a perimeter of the monolithic dielectric layer.

Referring now to FIG. 3F, a zoomed in cross-sectional illustration of a region 319 of one of the holes 320 in FIG. 3E is shown, in accordance with an embodiment. As shown, the hole 320 has a uniform sidewall profile through the second layers 305 and 306. In FIG. 3F, interface layer 311 is also shown.

Interface layer 311 may have a different chemical formula than the second layers 305 and 306 due to the bonding process used to form the combined substrate 310. However, the interface layer 311 may have a small thickness (e.g., up to approximately 5 nm or up to approximately 10 nm) and does not significantly impact the formation of the hole 320.

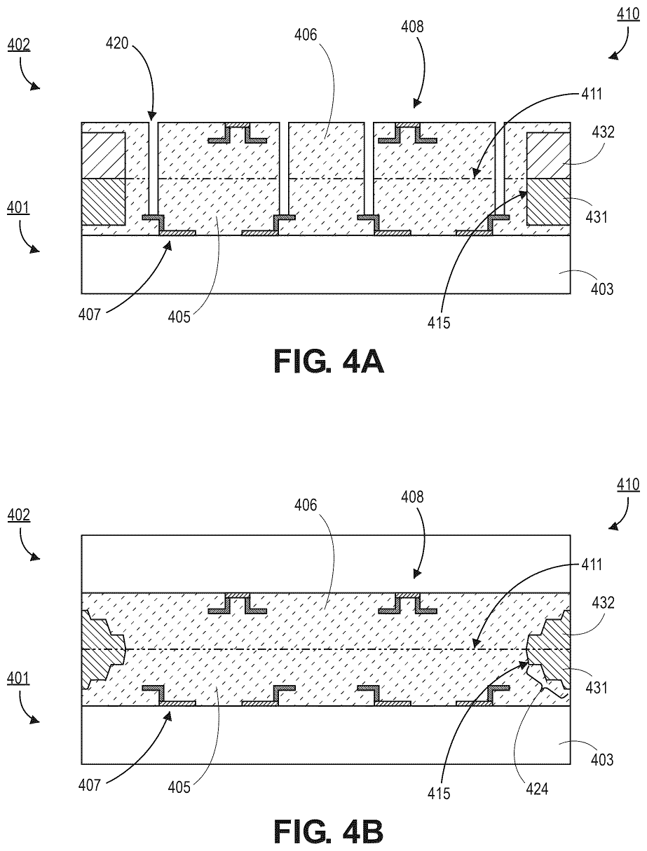

Referring now to FIGS. 4A and 4B, cross-sectional illustrations of combined substrates 410 in accordance with alternative architectures are shown, in accordance with different embodiments.

Referring now to FIG. 4A, a cross-sectional illustration of a combined substrate 410 with different fill layers 431 and 432 is shown, in accordance with an embodiment. In an embodiment, the combined substrate 410 in FIG. 4A may be similar to the combined substrate 310 described above, with the exception of the fill layers 431 and 432. For example, the combined substrate 410 may comprise a first substrate 401 that is bonded to a second substrate 402. First layer 403 may comprise a semiconductor material, and second layers 405 and 406 may be bonded together at interface 411 using processes similar to those described herein. In an embodiment, devices 407 and 408 may be embedded within the second layers 405 and/or 406. Holes 420 for forming vias may pass through portions of the second layers 405 and 406. In an embodiment, the second layers 405 and 406 may also comprise cavities 415 at the edge of the combined substrate 410.

However, instead of a monolithic fill material, the fill layer 431 may be a different material than the fill layer 432. In some embodiments, the fill layer 432 may comprise the same material as the second layer 406. For example, the fill layer 431 may comprise SiCN and the fill layer 432 may comprise SiO₂. In such an embodiment where the second layer 406 and the fill layer 432 comprise the same material, there may be no discernable boundary between the fill layer 432 and the second layer 406.

Referring now to FIG. 4B, a cross-sectional illustration of a combined substrate 410 is shown, in accordance with an additional embodiment. In an embodiment, the combined substrate 410 may be similar to the combined substrate 310 in FIG. 3D, with the exception of the profile of the cavity 415.

Instead of having a single rectangular recess, the cavity 415 may have a stepped surface 424. The stepped surface may include a plurality of different surface segments that comprise non-uniform slopes and/or lengths. In the illustrated embodiment, the top of the cavity 415 and the bottom of the cavity 415 are mirror images of each other. In other embodiments, a top of the cavity 415 may have a different profile than a bottom of the cavity 415.

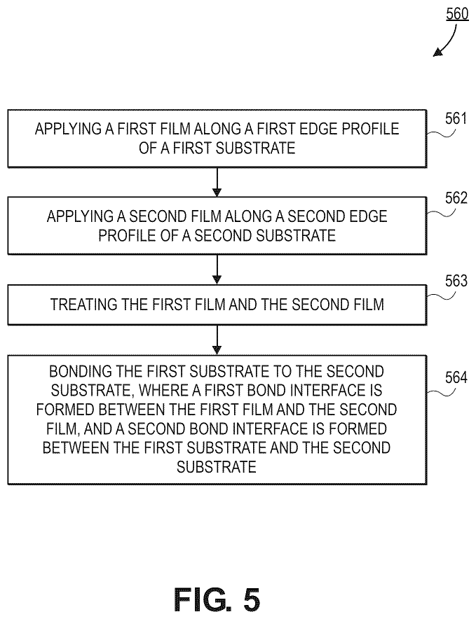

Referring now to FIG. 5, a flow diagram describing a process 560 for bonding two substrates together is shown, in accordance with an embodiment. In an embodiment, the process 560 may be similar to the process described herein with respect to FIG. 3A-3F.

In an embodiment, the process 560 may begin with operation 561, which comprises applying a first film along a first edge profile of a first substrate. In an embodiment, the first substrate may comprise a semiconductor layer with an overlying dielectric layer. The first edge profile may be a recess that extends down into the overlying dielectric layer at an edge of the first substrate. The first edge profile may be rectangular, stepped, curved, and/or the like. In an embodiment, the first film may comprise a dielectric material that is different than the dielectric material over the semiconductor layer. The first film may be selectively applied to the first edge profile with a masking process, a ring plasma process, or the like. In an embodiment, a planarization process (e.g., a CMP process) may be used to make a top surface of the first film substantially coplanar with a top surface of the dielectric layer provided over the semiconductor layer. Though, in other embodiments, the position of the top surface of the first film may be offset from the top surface of the dielectric layer in order to more precisely tune a bonding process.

In an embodiment, the process 560 may continue with operation 562, which comprises applying a second film along a second edge profile of a second substrate. In an embodiment, the second substrate may comprise a semiconductor layer with an overlying dielectric layer. The second edge profile may be a recess that extends down into the overlying dielectric layer at an edge of the second substrate. The second edge profile may be rectangular, stepped, curved, and/or the like. In an embodiment, the second film may comprise a dielectric material that is different than the dielectric material over the semiconductor layer. The second film may be selectively applied to the second edge profile with a masking process, a ring plasma process, or the like. In an embodiment, a planarization process (e.g., a CMP process) may be used to make a top surface of the second film substantially coplanar with a top surface of the dielectric layer provided over the semiconductor layer. Though, in other embodiments, the position of the top surface of the second film may be offset from the top surface of the dielectric layer in order to more precisely tune a bonding process.

In an embodiment, the process 560 may continue with operation 563, which comprises treating the first film and the second film. In an embodiment, the first film and the second film may be treated with a plasma treatment process. The plasma treatment process may be used in order to improve the adhesion between the first film and the second film during bonding. For example, in the case of SiCN, the plasma treatment may remove at least some of the carbon and nitrogen from the surface in order to leave dangling silicon bonds. The dangling silicon bonds may react with available oxygen in order to form Si—O—Si bonds during the substrate-to-substrate bonding process.

In an embodiment, the process 560 may continue with operation 564, which comprises bonding the first substrate to the second substrate, where a first bond interface is formed between the first film and the second film, and a second bond interface is formed between the first substrate and the second substrate. In an embodiment, the bonding operation may comprise a fusion bonding process that applies pressure and heat to the first substrate and the second substrate. In an embodiment, an annealing temperature may be up to approximately 200° C. or up to approximately 400° C. Though, higher temperatures may also be used in other embodiments.

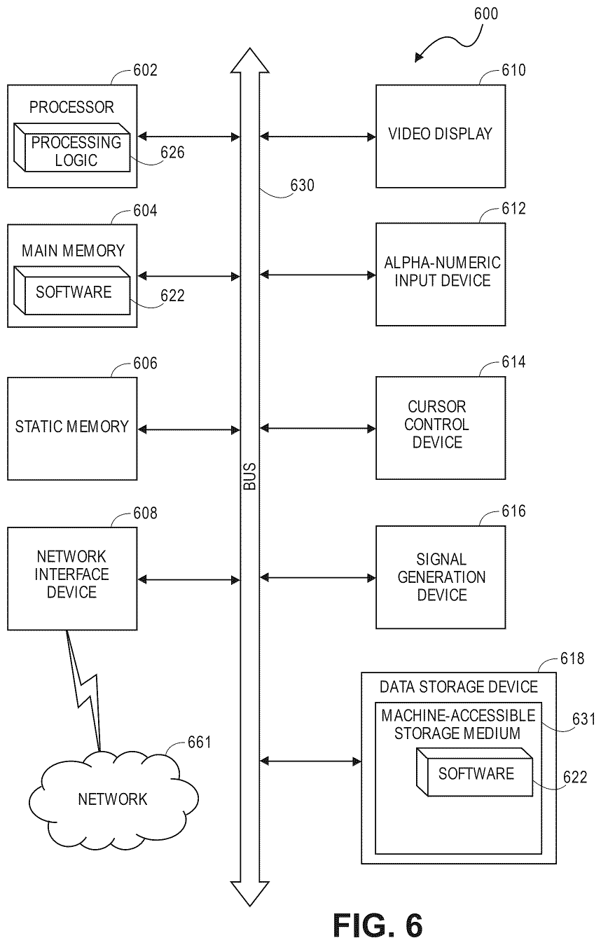

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a substrate, wherein the substrate comprises a semiconductor material;
a first layer on the substrate, wherein the first layer comprises a first dielectric material;
a device embedded within the first layer; and
a second layer embedded within the first layer, wherein the second layer comprises a second dielectric material, and wherein a sidewall of the second layer is exposed.

2. The apparatus of claim 1, wherein the second layer is a ring, and wherein the sidewall of the second layer is an outer edge of the ring.

3. The apparatus of claim 1, wherein a portion of the first layer separates the second layer from the substrate.

4. The apparatus of claim 1, wherein the second layer comprises a rectangular cross-section.

5. The apparatus of claim 1, wherein the second layer comprises a cross-section with a stepped surface.

6. The apparatus of claim 1, wherein the second layer comprises silicon, carbon, and nitrogen, or wherein the second layer comprises aluminum and oxygen.

7. The apparatus of claim 1, wherein the second layer comprises an internal interface, and wherein the internal interface comprises a Si—O—Si bond at the internal interface.

8. The apparatus of claim 1, further comprising:
an opening through a portion of the first layer, wherein the opening exposes a portion of the device.

9. The apparatus of claim 8, wherein the opening passes through only the first layer.

10. The apparatus of claim 1, wherein the device comprises a memory device or a logic device.

11. An apparatus, comprising:
a substrate;
a first layer over the substrate, wherein the first layer comprises a recess into a sidewall of the first layer;
a second layer that at least partially fills the recess, wherein the second layer is a different material than the first layer, and wherein the second layer forms a ring around at least a portion of the first layer.

12. The apparatus of claim 11, wherein the first layer comprises silicon and oxygen, and wherein the second layer comprises silicon, carbon, and nitrogen.

13. The apparatus of claim 11, wherein the first layer comprises a first device embedded in the first layer at a first surface that faces the substrate and a second device embedded in the first layer at a second surface that faces away from the substrate.

14. The apparatus of claim 13, wherein the first device is a memory device and the second device is a logic device.

15. The apparatus of claim 13, wherein the first device and the second device are used to in a 3D DRAM structure.

16. The apparatus of claim 11, wherein the second layer comprises a first sub-layer and a second sub-layer, wherein the first sub-layer is a different material than the second sub-layer.

17. A method, comprising:
applying a first film along a first edge profile of a first substrate;
applying a second film along a second edge profile of a second substrate; and
bonding the first substrate to the second substrate, wherein a first bond interface is formed between the first film and the second film, and a second bond interface is formed between the first substrate and the second substrate.

18. The method of claim 17, wherein the first film and the second film are applied with a selective deposition process that uses a mask to cover portions of the first substrate and the second substrate.

19. The method of claim 17, wherein the first film and the second film are selectively deposited with a ring plasma deposition process.

20. The method of claim 17, further comprising:
treating the first film and the second film with a plasma treatment before bonding.
